(19) United States
(12) Patent Application Publication
(10) Pub. No.: US 2007/0243691 A1
(43) Pub. Date: Oct. 18, 2007

(54) Manufacturing method of semiconductor device

(75) Inventors: Katsuyoshi Matsuura, Kawasaki (JP); Yuichiro Morozumi, Minato (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/494,768

(22) Filed: Jul. 28, 2006

(30) Foreign Application Priority Data
Apr. 13, 2006 (JP) 2006-111221

(51) Int. Cl. H01L 21/20

(52) U.S. Cl. 438/396

(57) ABSTRACT

Even in the case of manufacturing a fine ferroelectric memory, deterioration of a ferroelectric film can be prevented. An aluminum oxide film is formed by an ALD method to cover a ferroelectric capacitor formed above a semiconductor substrate, and after the aluminum oxide film is formed, annealing treatment is performed in an oxidizing gas atmosphere including ozone (O₃) having a strong oxidative effect, and the aluminum oxide film is made a densified film. Thereby, entry of hydrogen or the like into a ferroelectric film is inhibited, and reduction of the ferroelectric film is avoided.

### CROSS-REFERENCE TO RELATED APPLICATIONS

This application is based upon and claims the benefit of priority from the prior Japanese Patent Application No. 2006-111221, filed on Apr. 13, 2006, the entire contents of which are incorporated herein by reference.

### BACKGROUND OF THE INVENTION

1. Field of the Invention

The present invention relates to a manufacturing method of a semiconductor device having a capacitor structure.

2. Description of the Related Art

As nonvolatile memories capable of storing information even after power supply is turned off, a flash memory and a ferroelectric memory (FeRAM: Ferroelectric Random Access Memory) are known.

A flash memory has a floating gate buried in a gate insulating film of an insulated gate field effect transistor (IGFET: Insulated Gate Field Effect Transistor), and stores information by accumulating electric charges expressing stored information in the floating gate. For writing and erasing information, it is necessary to pass a tunnel current passing through the gate insulating film, and relatively high voltage is required.

On the other hand, a FeRAM stores information by utilizing a hysteresis characteristic of a ferroelectric. A ferroelectric capacitor including a ferroelectric as a capacitor dielectric between a pair of electrodes generates polarization in accordance with applied voltage between the electrodes, and has spontaneous polarization even after the applied voltage is removed. When the polarity of applied voltage is reversed, the polarity of spontaneous polarization is also reversed. Then, the spontaneous polarization is detected, and thereby information can be read out. A FeRAM operates at lower voltage as compared with a flash memory and can write at high speed with low power consumption.

FIGS. 17A and 17B are circuit diagrams each showing one example of a memory cell of a FeRAM.

The configuration shown in FIG. 17A is a 2T/2C type using two transistors Ta and Tb and two capacitors Ca and Cb for storage of information of one bit, which is generally used at present. In this type, a complimentary operation of storing information of “1” or “0” in one capacitor Ca, and storing the opposite information into the other capacitor Cb is performed. The 2T/2C type has the advantage of the configuration being strong against a process variation. On the other hand, this type has the disadvantage that the cell area is about twice as large as an 1T/1C type shown in FIG. 17B.

The configuration shown in FIG. 17B is the 1T/1C type using one transistor T1 or T2 and one capacitor C1 or C2 for storage of information of one bit. The 1T/1C type has the same configuration as a DRAM, and has the advantage that high integration is possible with a small cell area. On the other hand, this type has the disadvantage of requiring reference voltage for determining whether the electric charge read out of the memory cell is the information of “1” or the information of “0”. On this occasion, the reference cell which generates the reference voltage reverses polarization each time the information is read out, and therefore it deteriorates faster than the memory cell due to fatigue. The 1T/1C type also has the disadvantage that it has the margin of determination smaller as compared with the 2T/2C type, and is weak to a variation of process.

A ferroelectric film used for FeRAMs as shown in FIGS. 17A and 17B is easily reduced by hydrogen, and therefore, in order to obtain a good product as a FeRAM, a hydrogen diffusion prevention film which functions as a hydrogen barrier is required to be formed on the ferroelectric capacitor. This is because the process after formation of the ferroelectric capacitor includes a process step of using hydrogen such as a process step of growth of an interlayer insulating film. Until the FeRAM of the generation of, for example, 0.35 μm of the 2T/2C type, an aluminum oxide (Al₂O₃) film deposited by a sputtering method is used as a hydrogen diffusion prevention film.

For example, Japanese Patent Application Laid-open No. 2001-44375 describes that by depositing an Al₂O₃ film having film density exceeding 2.7 g/cm³ to cover all the capacitor processed into a band platform structure by using a sputtering method, a reducing gas such as hydrogen is prevented from reducing the ferroelectric film in a lateral direction of the capacitor. Such an Al₂O₃ film can be formed by RF sputter using, for example, an aluminum oxide target, and is deposited in an amorphous state with fewer particles. In this case, hydrogen does generate, and deterioration of the ferroelectric film by deposition of an aluminum oxide film does not occur.

However deposition of an aluminum oxide film by the conventional sputtering method cannot respond to a FeRAM of the generation of, for example, 0.18 μm. This is because the aspect ratio becomes large due to high integration of the FeRAM, and sufficient step coverage cannot be obtained by the conventional sputtering method.

Therefore, as a deposition method in place of a sputtering method of an aluminum oxide film, a deposition method by a chemical vapor deposition (CVD) method is being studied.

For deposition of an aluminum oxide film by a CVD method, tri-methyl aluminum (Al(CH₃)₃) (TMA: Tri-Methyl Aluminum) and water (H₂O) are used. In this deposition method, a method which is called atomic Layer Deposition (ALD: Atomic Layer Deposition) is adopted.

In deposition of an aluminum oxide film by the ALD method, after H₂O is supplied first to cause hydrogen groups (OH groups) to be adsorbed to cover all the front surface of the deposited film as shown in step S11 in FIG. 18, excess H₂O is evacuated and purged as shown in step S12. Next, after TMA is fed and reacted with the adsorbed OH groups to form Al₂O₃ of an atomic layer as shown in step S13, excess TMA is evacuated and purged as shown in step S14. By repeating a series of cycles of step S11 to step S14 from step S15 onward, an aluminum oxide film (Al₂O₃ film) is formed.

However, when an aluminum oxide film is deposited by the CVD method using TMA and H₂O as a hydrogen diffusion prevention film of a FeRAM, there is the problem that a ferroelectric film which is a capacitor film is deteriorated. This causes the trouble that it does not function as a FeRAM.

### SUMMARY OF THE INVENTION

The present invention is made in view of the above described problem, and has an object to provide a manufacturing method of a semiconductor device capable of preventing deterioration of a capacitor film even in the case of manufacturing a fine ferroelectric memory.

The manufacturing method of a semiconductor device of the present invention has the steps of forming a capacitor above a semiconductor substrate, forming an aluminum oxide film to cover the capacitor, and after forming the aluminum oxide film, performing heat treatment in an oxidizing gas atmosphere including ozone.

### BRIEF DESCRIPTION OF THE DRAWINGS

FIG. 1 is a characteristic chart showing a TDS analysis result of an Al₂O₃ film deposited by an ALD method using TMA and H₂O;

FIGS. 2A to 2C are schematic diagrams showing a manufacturing method of a ferroelectric memory (semiconductor device) of the present invention;

FIGS. 3A to 3C are sectional views showing a manufacturing method of a ferroelectric memory (semiconductor device) according to a first embodiment in sequence of process step;

FIGS. 4A to 4C are sectional views showing the manufacturing method of a ferroelectric memory (semiconductor device) according to the first embodiment in sequence of process step, continuing from FIG. 3C;

FIGS. 5A and 5B are sectional views showing the manufacturing method of a ferroelectric memory (semiconductor device) according to the first embodiment in sequence of process step, continuing from FIG. 4C;

FIG. 6 is a sectional view showing the manufacturing method of a ferroelectric memory (semiconductor device) according to the first embodiment in sequence of process step, continuing from FIG. 5B;

FIG. 7 is a schematic diagram showing a deposition method of an Al₂O₃ film by an ALD method using TMA and ozone (O₃) in sequence of process step;

FIGS. 8A to 8C are sectional views showing a manufacturing method of a ferroelectric memory (semiconductor device) according to a second embodiment in sequence of process step;

FIGS. 9A to 9C are sectional views showing the manufacturing method of a ferroelectric memory (semiconductor device) according to the second embodiment in sequence of process step, continuing from FIG. 8C;

FIGS. 10A to 10C are sectional views showing the manufacturing method of a ferroelectric memory (semiconductor device) according to the second embodiment in sequence of process step, continuing from FIG. 9C;

FIGS. 11A to 11C are sectional views showing the manufacturing method of a ferroelectric memory (semiconductor device) according to the second embodiment in sequence of process step, continuing from FIG. 10C;

FIGS. 12A to 12C are sectional views showing the manufacturing method of a ferroelectric memory (semiconductor device) according to the second embodiment in sequence of process step, continuing from FIG. 1C;

FIG. 13 is a characteristic chart showing a TDS analysis result when the Al₂O₃ film is deposited at a temperature of 300° C.;

FIG. 14 is a characteristic chart showing a TDS analysis result when the Al₂O₃ film is deposited at a temperature of 250° C.;

FIG. 15 is a characteristic chart showing a TDS analysis result when the Al₂O₃ film is deposited at a temperature of 200° C.;

FIG. 16 is a characteristic chart showing the fatigue characteristic of the ferroelectric capacitor;

FIGS. 17A and 17B are circuit diagrams each showing one example of a memory cell of a FeRAM; and

FIG. 18 is a schematic diagram showing a deposition method of an Al₂O₃ film by the ALD method using TMA and H₂O in sequence of process step.

### DETAILED DESCRIPTION OF THE PREFERRED EMBODIMENTS

### Gist of the Present Invention

As a result of repeating the study to look deep into the cause of deterioration of a ferroelectric film that is a capacitor film, the inventor of the present invention has found that since in the deposition method of an aluminum oxide protection film by the conventional CVD method, H₂O is used in large quantity, hydrogen or water is adsorbed in a ferroelectric film at the time of depositing the aluminum oxide film, and the ferroelectric film is reduced by heat treatment of the post-process.

Thus, the inventor of the present invention actually conducted the experiment of examining a content of H₂O existing in the aluminum oxide protection film by the conventional CVD method. In this case, the Al₂O₃ film was deposited to a thickness of about 20 nm on the silicon substrate by the ALD method using a batch type deposition apparatus, and evaluation was made by using a thermal desorption spectrometry (TDS) method.

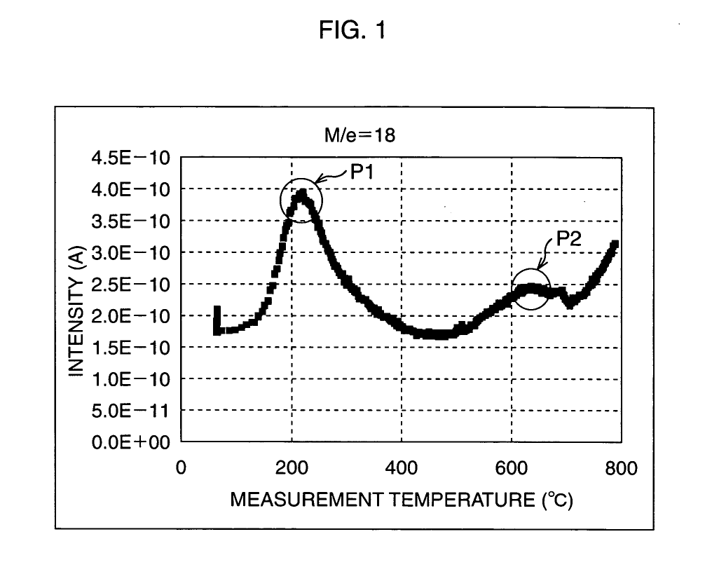

FIG. 1 is a characteristic chart showing the TDS analysis result of the Al₂O₃ film deposited by the ALD method using TMA and H₂O. In FIG. 1, only the spectrum of M/e=18 corresponding to H₂O is plotted.

Here, a temperature region P1 in the vicinity of 220° C. in FIG. 1 is considered to desorption of H₂O which was adsorbed onto the surface of the aluminum oxide film. A temperature region P2 in the vicinity of 650° C. is supposed to be H₂O generating as a result that OH groups of Al—OH bond existing in the aluminum oxide film in no small quantities react with one another by dehydration condensation reaction. In this case, the aluminum oxide film becomes a film which includes a number of voids, and is coarse and fragile as a protection film, a so-called porous film. It is conceivable that if H₂O comes out of the aluminum oxide film, the aluminum oxide itself is high in blocking tendency with respect to H₂O resistance, and therefore, the ferroelectric capacitor is in a so-called steamed state, as a result of which, the ferroelectric film is deteriorated. Due to deterioration of the ferroelectric film, the characteristic of the switching charge amount Qsw of the FeRAM is degraded.

Thus, based on the above view, the inventor of the present invention conceived the mode of the invention described as follows.

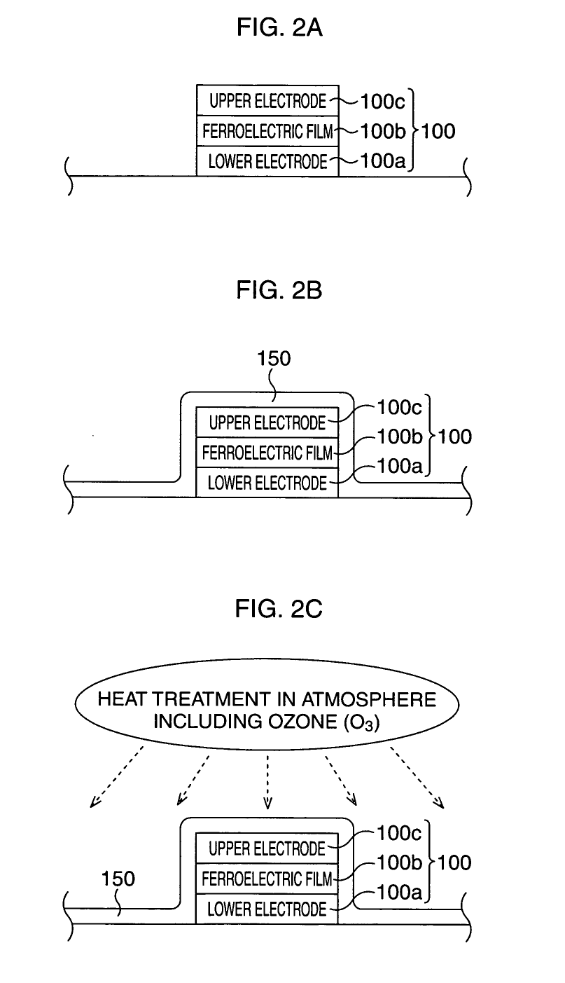

FIGS. 2A to 2C are schematic diagrams showing a manufacturing method of a ferroelectric memory (semiconductor device) of the present invention.

First, as shown in FIG. 2A, a ferroelectric capacitor 100 constituted of a lower electrode 100a, a ferroelectric film 100b that was a capacitor film, and an upper electrode 100c was formed above a semiconductor substrate, and thereafter, as shown in FIG. 2B, an aluminum oxide film (Al₂O₃ film) 150, which was a protection film, was formed to cover the ferroelectric capacitor 100 by an ALD method. After the aluminum oxide film 150 was formed, annealing treatment was performed in the oxidizing gas atmosphere including strongly oxidative ozone (O₃), and the aluminum oxide film 150 was made a dense film.

The present invention removes OH groups adhering into the aluminum oxide film 150 by ozone (O₃) even when forming the aluminum oxide film 150 by an ALD method using TMA and H₂O, and thereby makes it possible to prevent the ferroelectric film from being reduced by the heat treatment of the post process and being deteriorated. Further, the aluminum oxide film 150 is made a dense film, whereby even when hydrogen generates in the post process after deposition or the like of an interlayer insulating film, for example, it is made possible to inhibit entry of hydrogen or the like into the ferroelectric film, and to prevent deterioration of the ferroelectric film.

Japanese Patent Application Laid-open No. 2003-17664 describes that after the aluminum oxide film is deposited to cover the capacitor, heat treatment is performed in an atmosphere including an oxygen (O₂) gas. However, Japanese Patent Application Laid-open No. 2003-17664 describes nothing about heat treatment using ozone (O₃) with a strong oxidative effect, and therefore, it is obviously a different invention from the present invention.

Japanese Patent Application Laid-open No. 10-182300 described that ozone (O₃) annealing is performed on deposition of a ferroelectric film. However, Japanese Patent Application Laid-open No. 10-182300 describes nothing about providing a hydrogen diffusion prevention film constituted of an aluminum oxide film to prevent entry of hydrogen into a ferroelectric film, and ozone (O₃) annealing in Japanese Patent Application Laid-open No. 10-182300 has not relation to heat treatment using ozone (O₃) in the present invention.

Japanese Patent Application Laid-open No. 2004-193280 describes that an aluminum oxide film is deposited by using TMA and O₃. However, by performing only the treatment using ozone (O₃) at the time of deposition as in the case of Japanese Patent Application Laid-open No. 2004-193280, denseness of the film is insufficient, and a sufficient hydrogen barrier characteristic cannot be obtained. On the other hand, in the present invention, in order to make the aluminum oxide film a denser film, heat treatment using ozone (O₃) for a long time is performed after formation of the aluminum oxide film.

### CONCRETE EMBODIMENTS OF THE PRESENT INVENTION

Next, various embodiments of the present invention will be described with reference to the attached drawings.

### First Embodiment

Hereinafter, a first embodiment of the present invention will be described.

In the first embodiment, a stack type ferroelectric memory in which electrical connection of an upper electrode of a ferroelectric capacitor is obtained from above, and electrical connection of a lower electrode of the ferroelectric capacitor is obtained from below will be described.

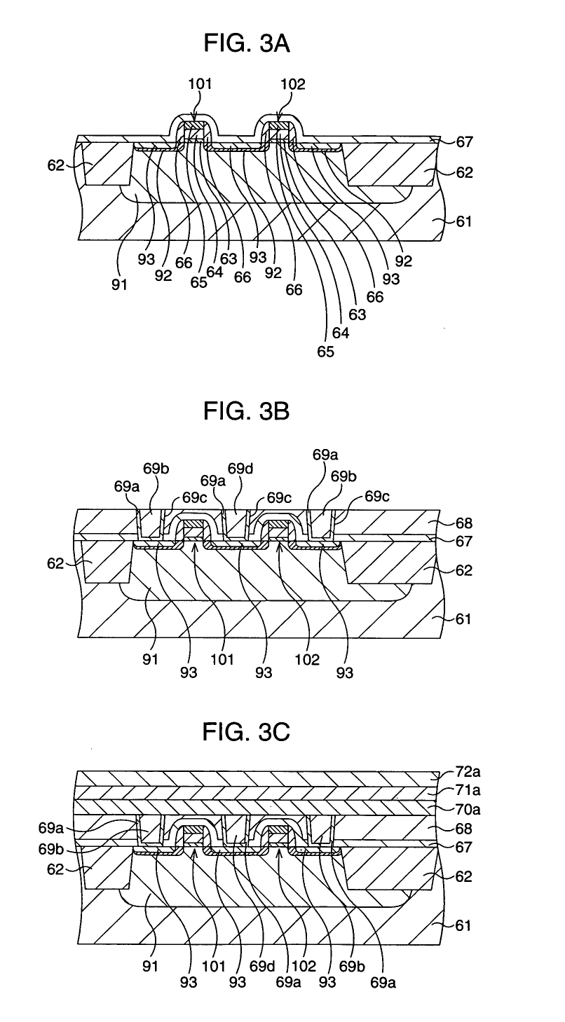

FIGS. 3A to 6 are sectional views showing a manufacturing method of a ferroelectric memory (semiconductor device) according to the first embodiment in sequence of process step.

In the first embodiment, first as shown in FIG. 3A, an element isolation insulating film 62, and, for example, a p-well 91 are formed in a semiconductor substrate 61, MOSFETs 101 and 102 are further formed above the semiconductor substrate 61, and for example, silicon oxynitride film (SiON film) 67 which covers each MOSFET is formed.

In concrete, first, the element isolation insulating film 62 is formed in an element isolation region of the semiconductor substrate 61 such as an Si substrate by, for example, an STI (Shallow Trench Isolation) method, and an element forming region is defined. Subsequently, for example, boron (B) is ion-implanted in a front surface of the element formation region of the semiconductor substrate 61 under the conditions of, for example, energy of 300 keV, and a dose amount of 3.0×10¹³ cm⁻¹², and the p-well 91 is formed. Subsequently, a silicon oxide film of a thickness of about 3 nm is formed above the semiconductor substrate 61 by, for example, a thermal oxidation method. Subsequently, a polycrystalline silicon film of a thickness of about 180 nm is formed on the silicon oxide film by a CVD method. Subsequently, patterning by which the polycrystalline silicon film and the silicon oxide film are left on only the element forming region is performed, and gate insulating films 63 constituted of the silicon oxide film, and gate electrodes 64 constituted of the polycrystalline silicon film are formed.

Subsequently, with the gate electrodes 64 as a mask, for example, phosphorus (P) is ion-implanted in the front surface of the semiconductor substrate 61 under the conditions of, for example, energy of 13 keV and a dose amount of 5.0×10¹⁴ cm⁻², and an n⁻-type low-concentration diffusion layer 92 is formed. Subsequently, after an SiO₂ film of a thickness of about 300 nm is formed on the entire surface by a CVD method, anisotropic etching is performed, and the SiO₂ film is left on only the side walls of the gate electrodes 64 to form side walls 66.

Subsequently, with the gate electrodes 64 and the side walls 66 as a mask, for example, arsenide (As) is ion-implanted in the front surface of the semiconductor substrate 61 under the conditions of, for example, energy of 10 keV and a dose amount of 5.0×10¹⁴ cm⁻², and an n⁺-type high-concentration diffusion layer 93 is formed.

Subsequently, for example, a Ti film is deposited on the entire surface by, for example, a sputtering method. Thereafter, by performing thermal treatment at a temperature of 400° C. to 900° C., the polycrystalline film of the gate electrode 64 and the Ti film silicide-react with each other, and a silicide layer 65 is formed on a top surface of the gate electrode 64. Thereafter, by using hydrofluoric acid or the like, the unreacted Ti film is removed. Thereby, the MOSFETs 101 and 102 including source/drain diffusion layers constituted of the gate insulating films 63, the gate electrodes 64, the silicide layers 65, the side walls 66, and the low-concentration diffusion layers and the high-concentration diffusion layers 93 are formed above the semiconductor substrate 61. In this embodiment, formation of an n-channel type MOSFET is described as an example, but a p-channel type MOSFET may be formed. Subsequently, an SiON film 67 of a thickness of about 200 nm is formed on the entire surface by a plasma CVD method.

Next, as shown in FIG. 3B, after a silicon oxide film of a thickness of about 1000 nm is deposited on the SiON film 67 by a plasma CVD method, this is flattened by a CMP method, and an interlayer insulating film 68 constituted of a silicon oxide film is formed to a thickness of about 700 nm. Subsequently, via holes 69c which reach the high-concentration diffusion layers 93 of the respective MOSFETs are formed each with a diameter of, for example, about 0.25 μm in the interlayer insulating film 68 and the SiON film 67. Thereafter, by successively stacking a TiN film of a thickness of about 50 nm and a Ti film of a thickness of about 30 nm in each of the via holes 69c by, for example, a sputtering method, glue films 69a are formed. Subsequently, after a W film of a thickness sufficient to fill an inside of each of the via holes 69c is further deposited by a CVD method, flattening of the W film is performed by a CMP method until the front surface of the interlayer insulating film 68 is exposed, and thereby, W plugs 69b and 69d are formed in the via holes 69c. In this case, the W plug 69b connects to one of the source/drain diffusion layers of each MOSFET, and the W plug 69d connects to the other one.

Next, as shown in FIG. 3C, an Ir film 70a, a ferroelectric film 71a and an IrO₂ film 72a are sequentially stacked on the entire surface.

More specifically, first, by a sputtering method, for example, the Ir film 70a of a thickness of about 200 nm is deposited on the entire surface under the deposition conditions of, for example, Ar gas pressure of 0.11 Pa, DC power of 0.5 kW, and a deposition temperature of 500° C. for 335 seconds. The Ir film 70a corresponds to the lower electrode film of the ferroelectric capacitor.

Subsequently, by a MO-CVD method, the ferroelectric film 71a composed of lead zirconate titanate (PZT) of a thickness of about 120 nm is deposited under the deposition conditions of, for example, deposition pressure of 667 Pa (5 Torr), and a deposition temperature of 620° C. for 620 seconds. The ferroelectric film 71a corresponds to the capacitor film of the ferroelectric capacitor. In the MO-CVD method for forming the ferroelectric film 71a composed of PZT, use of a vaporizer is preferable. In this case, the respective solid raw materials of Pb, Zr and Ti are dissolved into organic compound solutions, the dissolved solutions are evaporated by the vaporizer to generate source gases, and the source gases are introduced into the reactor to deposit the ferroelectric film 71a. An example of source and the flow rates on deposition of the ferroelectric film 71a is shown in the following Table 1.

TABLE 1

| | | |
|---|---|---|
| SOLVENT | THF | 0.474 ml/min |
| | (Tetra Hydro Furan: C₄H₈O) | |
| SOURCE | Pb(DPM)₂ | 0.326 ml/min |
| | (concentration: 0.3 × 10³ mol/m³, | |
| | dissolved in THF | |
| | solution) | |
| | Zr(dmhd)₄ | 0.200 ml/min |
| | (concentration: 0.3 × 10³ mol/m³, | |
| | dissolved in THF | |
| | solution) | |
| | Ti(O-iPr)₂(DPM)₂ | 0.200 ml/min |
| | (concentration: 0.3 × 10³ mol/m³, | |
| | dissolved in THF | |
| | solution) | |

Subsequently, by a sputtering method, the IrO₂ film 72a of a thickness of about 200 nm is deposited on the ferroelectric film 71a under the deposition conditions of, for example, gas pressure of 0.8 Pa, an Ar gas flow rate of 100 sccm, an O₂ gas flow rate of 100 sccm, and DC power of 1.0 kW for 79 seconds. The IrO₂ film 72a corresponds to an upper electrode film of the ferroelectric capacitor.

By using IrO₂ that is a conductive oxide as the upper electrode film, hydrogen-induced degradation resistance of the ferroelectric film 71a can be enhanced. For example, in the case of using Pt as the upper electrode film, Pt has catalytic action with respect to a hydrogen molecule, and therefore, hydrogen radicals are generated to reduce the ferroelectric film 71a to cause degradation to it. On the other hand, IrO₂ does not have catalytic action, and therefore, hydrogen radicals are hardly generated, thus remarkably enhancing hydrogen-induced degradation resistance of the ferroelectric film 71a.

Thereafter, in order to repair the damage to the ferroelectric film 71a by deposition of the IrO₂ film (upper electrode film) 72a, recovering annealing is performed. As the recovering annealing in this case, furnace annealing at a temperature of about 550° C. in an O₂ atmosphere is performed for about 60 minutes, for example.

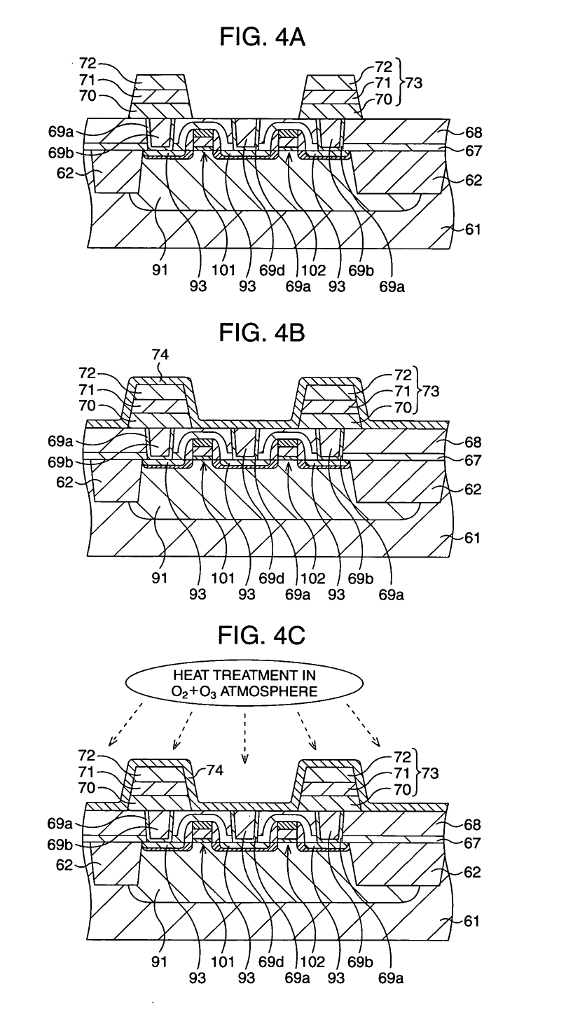

Next, as shown in FIG. 4A, by using patterning and etching techniques, a ferroelectric capacitor 73 including a lower electrode 70 constituted of the Ir film 70a, a ferroelectric film 71 constituted of PZT, and an upper electrode 72 constituted of the IrO₂ film 72a is formed.

More specifically, first, a hard mask (not shown) which covers only a ferroelectric capacitor forming region on the IrO₂ film 72a is formed. In this case, the hard mask is formed by forming a titanium nitride film (TiN) and a silicon oxide film using TEOS (tetraethyl orthosilicate) in sequence, and patterning them. Subsequently, by etching using the hard mask, the IrO₂ film 72a, the ferroelectric film 71a and the Ir film 70a in the region except for the ferroelectric capacitor forming region are removed. Thereby, the ferroelectric capacitor 73 is formed.

Next, as shown in FIG. 4B, an Al₂O₃ film 74 favorable in step coverage is formed to cover the ferroelectric capacitor 73 and the interlayer insulating film 68. In this embodiment, the Al₂O₃ film 74 is formed with a thickness of about 20 nm by an atomic layer deposition (ALD: Atomic Layer Deposition) method using a batch type deposition apparatus.

On formation of the Al₂O₃ film 74 using the ALD method, it is possible to form it by an ALD method using TMA and H₂O, but from the viewpoint of making the Al₂O₃ film 74 a more densified film, formation of the film is performed by the ALD method using TMA and ozone (O₃) in this embodiment.

More specifically, in this embodiment, a deposition process step using TMA which is liquid at a room temperature as an Al source, and an oxidation process step under the atmosphere of oxygen (O₂) and ozone (O₃) are alternately switched with a vacuum purge process step interposed between the process steps, and this is repeated by about 210 cycles to form the Al₂O₃ film 74.

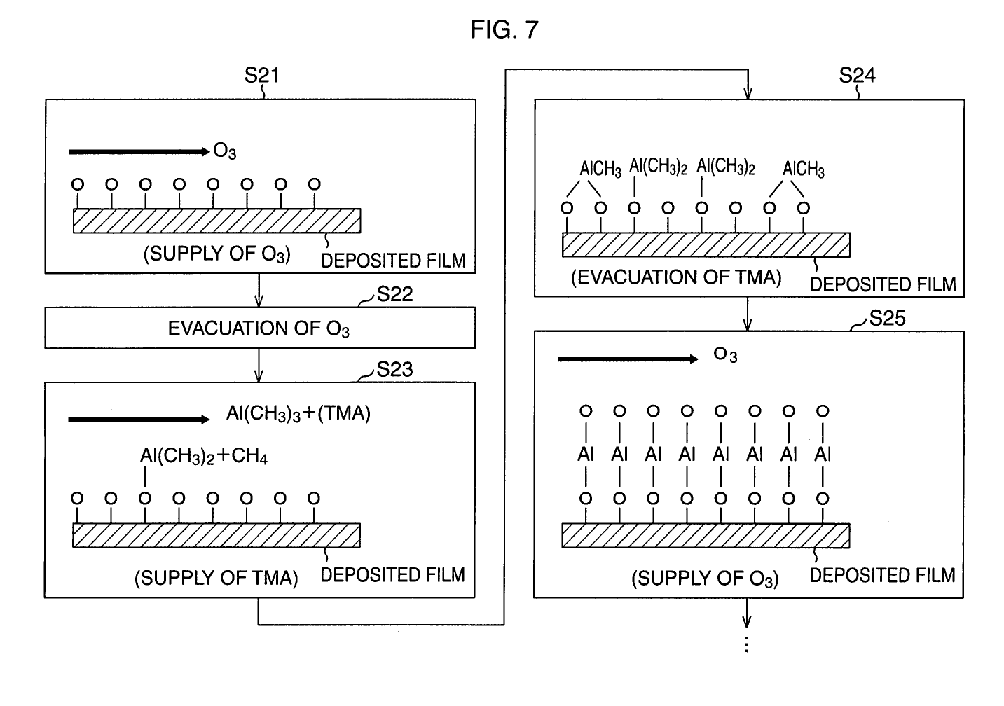

More specifically, first, as shown in step S21 in FIG. 7, the front surface of the deposited film is oxidized by supplying ozone (O₃), and thereafter, excess ozone (O₃) is evacuated and purged as shown step S22. Next, as shown in step S23, TMA is fed and reacted with oxygen groups on the front surface of the deposited film to form Al₂O₃ of an atomic layer, and thereafter, excess TMA is evacuated and purged as shown in step S24. A cycle of series of the steps of step S21 to step S24 is repeated from step S25 and thereafter, and thereby, the Al₂O₃ film 74 is formed.

In the deposition process step using TMA, deposition is performed under the conditions of, for example, a substrate temperature of 300° C., gas pressure of 40 Pa (0.3 Torr), and a TMA gas flow rate of 100 sccm for 5 seconds. The oxidation process step using ozone (O₃) is performed under the conditions of, for example, a substrate temperature of 300° C., gas pressure of 133 Pa (1.0 Torr), an O₂+O₃ gas flow rate of 10 slm, and an O₃ concentration of 200 g/Nm³ for 15 seconds. Since TMA is relatively high in vapor pressure, it is introduced into the batch type deposition apparatus in the state it is heated to a temperature of 40° C. and is gasified by the vapor pressure.

After formation of the Al₂O₃ film 74 is finished, densification annealing is subsequently performed by increasing the temperature in the same apparatus (in-situ) under an atmosphere of oxygen (O₂) and ozone (O₃) as shown in FIG. 4C. On this occasion, increase of temperature is performed at about 10° C./min, and in order to stabilize the temperature, the temperature is kept for at least 30 minutes after being increased. The densification annealing is performed under the conditions of, for example, the substrate temperature of 500° C., gas pressure of 133 Pa (1.0 Torr), an O₂+O₃ gas flow rate of 10 slm, and O₃ concentration of 200 g/Nm³ for 30 minutes.

In this embodiment, the temperature of densification annealing after formation of the Al₂O₃ film 74 is set at about 500° C., but the annealing temperature for obtaining the effect of the present invention can be set in the range of 400° C. to 700° C. inclusive. This is because when the annealing temperature is less than 400° C., the problem of insufficient densification of Al₂O₃ film 74 occurs, and when the annealing temperature exceeds 700° C., the problem that Pb is desorbed from PZT composing the ferroelectric film 71 and fatigue characteristics are degraded occurs. In this embodiment, the time of densification annealing after formation of the Al₂O₃ film 74 is set at about 30 minutes, but annealing time for obtaining the effect of the present invention can be set in the range of 10 minutes to 120 minutes inclusive. This is because, when the annealing time is less than 10 minutes, the problem of dependence according to the wafer position appears in the batch type apparatus in which the densification annealing is performed occurs, and when the annealing temperature exceeds 120 minutes, densification of the Al₂O₃ film 74 is sufficient, but the problem of reduction in throughput occurs.

The Al₂O₃ film 74 becomes a densified film by the annealing treatment in an atmosphere including ozone (O₃) having strong oxidative property. Thereby, even when hydrogen occurs in the post process of deposition of, for example, an interlayer insulating film or the like, entry of hydrogen into the ferroelectric film 71 can be inhibited, and deterioration of the ferroelectric film 71 can be prevented. Further, when deposition of the Al₂O₃ film 74 is performed by an ALD method using TMA and H₂O, OH groups existing in the Al₂O₃ film 74 can be collectively removed, and deterioration of the ferroelectric film 71 by a so-called steamed state can be avoided.

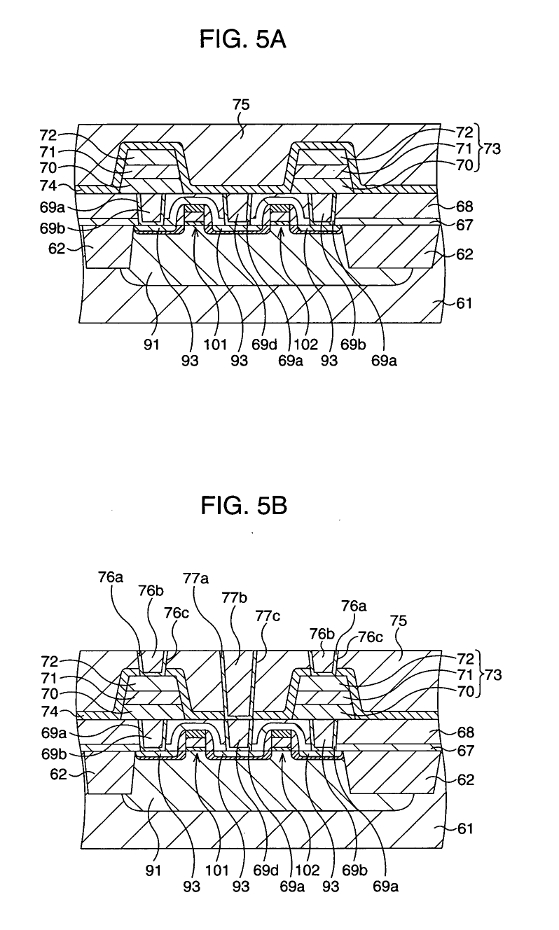

Next, as shown in FIG. 5A, after an SiO₂ film of a thickness of about 1500 nm is deposited on the Al₂O₃ film 74 by an HDP-CVD (high desification plasma CVD) method, the SiO₂ film is flattened to the position of about 300 nm from a top of the upper electrode 72 by using a CMP method, and an interlayer insulating film 75 is formed.

In this embodiment, the interlayer insulating film 75 is formed by an HDP-CVD method, and this is because when miniaturization advances as the FeRAM of a stacked structure, in the interlayer insulating film from the second layer and thereafter, a wiring interval is narrowed with an ordinary plasma CVD method by TEOS, and there is a fear of a so-called “void” occurs. When a large “void” occurs with respect to the wiring width, the film thickness of the insulating film which retains the side of the wiring becomes thin, and a crack occurs from the portion of the “void” due to thermal expansion or the like of the wiring, thus reducing reliability of wiring.

On formation of the interlayer insulating film 75 by the HDP-CVD method, the film is deposited by using SiH₄, Ar, O₂ or the like as a deposition gas. On this occasion, by applying large bias to the semiconductor substrate 61, sputtering by Ar⁺ and deposition of SiO₂ by SiH₄ and O₂ are caused to progress at the same time, and narrow spaces between the wirings are filled with the insulating film. However, in the HDP-CVD method, at the same time when Ar⁺ is induced by biasing the semiconductor substrate 61, H⁺ is also attracted into the semiconductor substrate 61. Therefore, in the case of using the HDP-CVD method, it is effective to use the densified Al₂O₃ film 74.

Next, via holes 76c in which the front surfaces of the upper electrodes 72 are exposed are first formed in the interlayer insulating film 75 and the Al₂O₃ film 74. Thereafter, the final recovering annealing is performed. As the recovering annealing in this case, furnace annealing, for example, at a temperature of about 500° C. under an O₂ atmosphere is performed for about 60 minutes.

Next, a via hole 77c in which the front surface of the W plug 69d is exposed is formed in the interlayer insulating film 75 and the Al₂O₃ film 74. Thereafter, as shown in FIG. 5B, a TiN film of a thickness of about 10 nm is deposited in the via holes 76c and the via hole 77c by, for example, a sputtering method, and glue films 76a and a glue film 77a are formed. Subsequently, after W films of a thicknesses sufficient to fill the via holes 76c and the via hole 77c are deposited, the W films are flattened by a CMP method until the front surface of the interlayer insulating film 75 is exposed, and thereby, W plugs 76b are formed in the via holes 76c and a W plug 77b is formed in the via hole 77c.

As compared with a normal logic product, a FeRAM has a step height corresponding to the ferroelectric capacitor 73, and therefore, an aspect ratio of the contact to the semiconductor substrate 61 from the metal wiring layer becomes large. Formation of the via holes 77c and 69c by etching as a single unit requires the newest equipment because it becomes difficult to bury the glue film in addition to that etching itself is difficult. By forming the W plugs in two stages as in this embodiment, not only yield of the FeRAM is enhanced, but also development cost and process cost can be reduced since the apparatus which is conventionally used can be used for forming plugs.

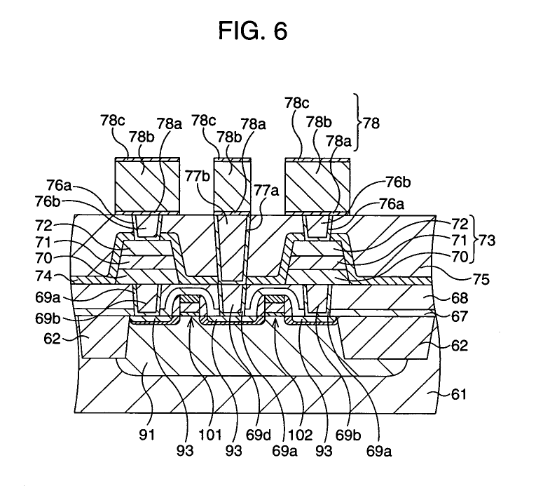

Next, as shown in FIG. 6, a metal wiring layer 78 constituted of a glue film 78a, a wiring film 78b and a glue film 78c is formed.

More specifically, first, on the entire surface, a Ti film of a thickness of about 60 nm, a TiN film of a thickness of about 30 nm, an AlCu alloy film of a thickness of about 400 nm, a Ti film of a thickness of about 5 nm, and a TiN film of a thickness of about 70 nm are sequentially stacked by, for example, a sputtering method. Subsequently, by using a photolithography technique, the stacked film is patterned into a predetermined shape, and on each of the W plugs 76b and 77b, the metal wiring layer 78 constituted of the glue film 78a constituted of the Ti film and the TiN film, the wiring film 78b constituted of the AlCu alloy film, and the glue film 78c constituted of the Ti film and the TiN film is formed.

Thereafter, after formation of an interlayer insulating film and formation of contact plugs are performed, the metal wiring layer after the second layer and thereafter is formed, and a cover film constituted of a TEOS-SiO₂ film and an SiN film is finally formed, and a ferroelectric memory according to this embodiment having the ferroelectric capacitor 73 is completed.

### Second Embodiment

Hereinafter, a second embodiment of the present invention will be described.

In the first embodiment, the stack type ferroelectric memory is described, and in the second embodiment, a planar type ferroelectric memory in which electrical connection of the upper electrode and the lower electrode of a ferroelectric capacitor is obtained from above will be described.

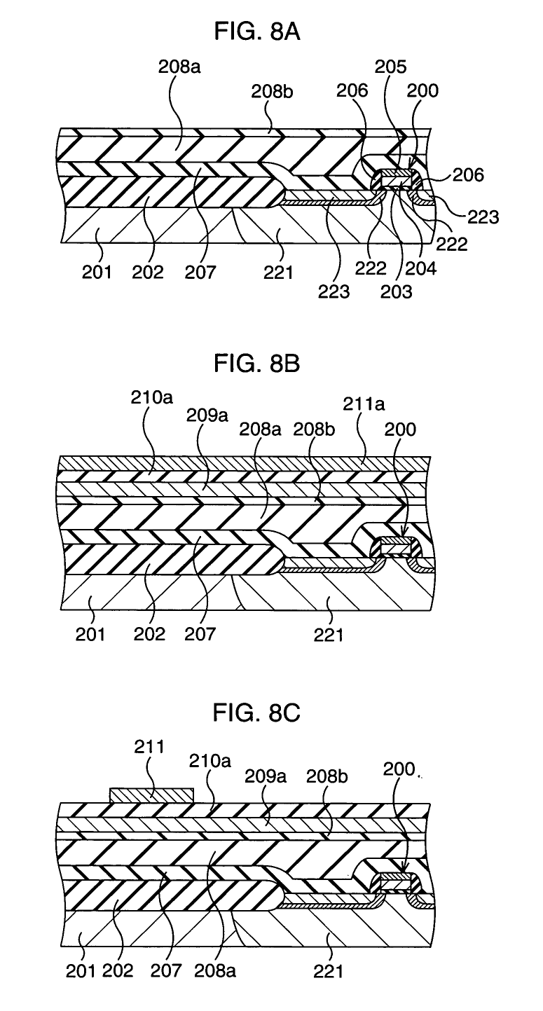

FIGS. 8A to 12C are sectional views showing a manufacturing method of a ferroelectric memory (semiconductor device) according to the second embodiment in sequence of process step.

In the second embodiment, first, as shown in FIG. 8A, an element isolation insulating film 202, and, for example, a p-well 221 are formed in a semiconductor substrate 201, a MOSFET 200 is further formed above the semiconductor substrate 201, and on the MOSFET 200, a silicon oxynitride film (SiON film) 207, a silicon oxide film 208a and an Al₂O₃ film 208b are formed in sequence.

In concrete, first, the element isolation insulating film 202 is formed in an element isolation region of the semiconductor substrate 201 such as an Si substrate by, for example, an LOCOS (Local Oxidation of Silicon) method, and an element forming region is defined. Subsequently, for example, boron (B) is ion-implanted in a front surface of the element forming region of the semiconductor substrate 201 under the conditions of, for example, energy of 300 keV, and a dose amount of 3.0×10¹³ cm⁻², and the p-well 221 is formed. Subsequently, a silicon oxide film of a thickness of about 3 nm is formed above the semiconductor substrate 201 by, for example, a thermal oxidation method. Subsequently, a polycrystalline silicon film of a thickness of about 180 nm is formed on the silicon oxide film by a CVD method. Subsequently, patterning by which the polycrystalline silicon film and the silicon oxide film are left on only the element forming region is performed, and a gate insulating film 203 constituted of the silicon oxide film, and a gate electrode 204 constituted of the polycrystalline silicon film are formed.

Subsequently, with the gate electrode 204 as a mask, for example, phosphorus (P) is ion-implanted in the front surface of the semiconductor substrate 201 under the conditions of, for example, energy of 13 keV and a dose amount of 5.0×10¹⁴ cm⁻², and an n⁻-type low-concentration diffusion layer 222 is formed. Subsequently, after an SiO₂ film of a thickness of about 300 nm is formed on the entire surface by a CVD method, anisotropic etching is performed, and the SiO₂ film is left on only the side walls of the gate electrode 204 to form side walls 206.

Subsequently, with the gate electrode 204 and the side walls 206 as a mask, for example, arsenide (As) is ion-implanted in the front surface of the semiconductor substrate 201 under the conditions of energy of 10 keV and a dose amount of 5.0×10¹⁴ cm⁻², and an n⁺-type high-concentration diffusion layer 223 is formed.

Subsequently, for example, a Ti film is deposited on the entire surface by, for example, a sputtering method. Thereafter, by performing thermal treatment at a temperature of 400° C. to 900° C., the polycrystalline film of the gate electrode 204 and the Ti film silicide-react with each other, and a silicide layer 205 is formed on a top surface of the gate electrode 204. Thereafter, by using hydrofluoric acid or the like, the unreacted Ti film is removed. Thereby, a MOSFET 200 including a source/drain diffusion layer constituted of the gate insulating films 203, the gate electrode 204, the silicide layer 205, the side walls 206, and the low-concentration diffusion layer 222 and the high-concentration diffusion layer 223 is formed above the semiconductor substrate 201. In this embodiment, formation of an n-channel type MOSFET is described as an example, but a p-channel type MOSFET may be formed.

Subsequently, a silicon oxynitride film 207 of a thickness of about 200 nm is formed to cover the MOSFET 200 by a CVD method. Subsequently, a silicon oxide film 208a of a thickness of about 700 nm is formed on the silicon oxynitride film 207 by a CVD method. Subsequently, by polishing the silicon oxide film 208a by a CMP (Chemical Mechanical Polishing) method, its front surface is flattened. Thereafter, by performing annealing treatment at a temperature of 650° C. for 30 minutes under an N₂ atmosphere, degassing of the silicon oxide film 208a is performed. The silicon oxynitride film 207 is formed to prevent hydrogen-induced degradation of the gate insulating film 203 and the like on forming the silicon oxide film 208a.

Subsequently, an Al₂O₃ film 208b of a thickness of about 20 nm is formed on the silicon oxide film 208a by, for example, a sputtering method as a lower electrode adhesion film. As the lower electrode adhesion film, a Ti film, a TiOₓ film or the like of a thickness of about 20 nm may be formed.

Next, as shown in FIG. 8B, an Ir film 209a, a ferroelectric film 210a and an IrO₂ film 211a are sequentially stacked on the entire surface.

More specifically, first, by a sputtering method, for example, the Ir film 209a of a thickness of about 200 nm is deposited on the entire surface under the deposition conditions of, for example, Ar gas pressure of 0.11 Pa, DC power of 0.5 kW, and a deposition temperature of 500° C. for 335 seconds. The Ir film 209a corresponds to the lower electrode film of a ferroelectric capacitor.

Subsequently, by an MO-CVD method, the ferroelectric film 210a composed of PZT of a thickness of about 120 nm is deposited on the Ir film 209a under the deposition conditions of, for example, deposition pressure of 667 Pa (5 Torr), and a deposition temperature of 620° C. for 620 seconds. The ferroelectric film 210a corresponds to the capacitor film of the ferroelectric capacitor. In the MO-CVD method for forming the ferroelectric film 210a composed of PZT, use of a vaporizer is preferable. In this case, the respective solid raw materials of Pb, Zr and Ti are dissolved into organic compound solutions, the dissolved solutions are evaporated by the vaporizer to generate source gases, and the source gases are introduced into the reactor to deposit the ferroelectric film 210a. An example of the source and the flow rates on deposition of the ferroelectric film 210a is shown in the above described Table 1.

Subsequently, by a sputtering method, the IrO₂ film 211a of a thickness of about 200 nm is deposited on the ferroelectric film 210a under the deposition conditions of, for example, gas pressure of 0.8 Pa, an Ar gas flow rate of 100 sccm, an O₂ gas flow rate of 100 sccm, and DC power of 1.0 kW for 79 seconds. The IrO₂ film 211a corresponds to an upper electrode film of the ferroelectric capacitor.

Thereafter, in order to repair the damage to the ferroelectric film 210a by deposition of the IrO₂ film (upper electrode film) 211a, recovering annealing is performed. As the recovering annealing in this case, furnace annealing at a temperature of about 550° C. in an O₂ atmosphere is performed for about 60 minutes, for example.

Next, after back surface cleaning of the semiconductor substrate 201 is performed, the IrO₂ film 211a is patterned, and thereby, an upper electrode 211 constituted of the IrO₂ film is formed as shown in FIG. 8C. Thereafter, recovering annealing treatment at a temperature of about 650° C. for about 60 minutes is performed under an O₂ atmosphere. The heat treatment is for repairing a physical damage or the like which the ferroelectric film 210a is subjected when the upper electrode 211 is formed.

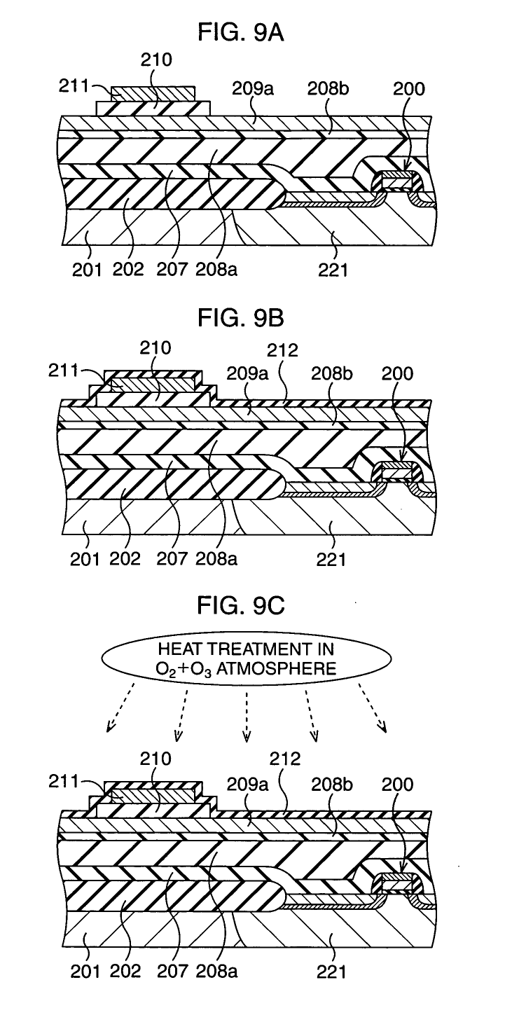

Next, as shown in FIG. 9A, by performing patterning of the ferroelectric film 210a, a ferroelectric film 210 to be a capacitor film of a ferroelectric capacitor is formed. Thereafter, oxygen annealing for prevention of peeling-off of an Al₂O₃ film which will be formed later is performed.

Next, as shown in FIG. 9B, an Al₂O₃ film 212 favorable in step coverage is formed to cover the upper electrode 211, the ferroelectric film 210 and the Ir film 209a. In this embodiment, the Al₂O₃ film 212 is formed with a thickness of about 20 nm by an ALD method using a batch type deposition apparatus.

On formation of the Al₂O₃ film 212 using the ALD method, it is possible to form it by an ALD method using TMA and H₂O, but from the viewpoint of making the Al₂O₃ film 212 a more densified film, formation of the film is performed by the ALD method using TMA and ozone (O₃) in this embodiment.

More specifically, in this embodiment, a deposition process step using TMA which is liquid at a room temperature as an Al source, and an oxidation process step under the atmosphere of oxygen (O₂) and ozone (O₃) are alternately switched with a vacuum purge process step interposed between the process steps, and this is repeated by about 210 cycles to form the Al₂O₃ film 212.

More specifically, first, as shown in step S21 in FIG. 7, the front surface of the deposited film is oxidized by supplying ozone (O₃), and thereafter, excess ozone (O₃) is evacuated and purged as shown step S22. Next, as shown in step S23, TMA is fed and reacted with oxygen groups on the front surface of the deposited film to form Al₂O₃ of an atomic layer, and thereafter, excess TMA is evacuated and purged as shown in step S24. A cycle of a series of steps of step S21 to step S24 are repeated from step S25 and thereafter, the Al₂O₃ film 212 is formed.

In the deposition process step using TMA, deposition is performed under the conditions of, for example, a substrate temperature of 300° C., gas pressure of 40 Pa (0.3 Torr), and a TMA gas flow rate of 100 sccm for 5 seconds. The oxidation process step using ozone (O₃) is performed under the conditions of, for example, a substrate temperature of 300° C., gas pressure of 133 Pa (1.0 Torr), an O₂+O₃ gas flow rate of 10 slm, and an O₃ concentration of 200 g/Nm³ for 15 seconds. Since TMA is relatively high in vapor pressure, it is introduced into the batch type deposition apparatus in the state in which it is heated to a temperature of 40° C. and is gasified by the vapor pressure.

After formation of the Al₂O₃ film 212 is finished, densification annealing is subsequently performed by increasing the temperature in-situ under an atmosphere of oxygen (O₂) and ozone (O₃) as shown in FIG. 9C. On this occasion, increase of temperature is performed at about 10° C./min, and in order to stabilize the temperature, the temperature is kept at least for 30 minutes after being increased. The densification annealing is performed under the conditions of, for example, a substrate temperature of 500° C., gas pressure of 133 Pa (1.0 Torr), an O₂+O₃ gas flow rate of 10 slm, and O₃ concentration of 200 g/Nm³ for 30 minutes.

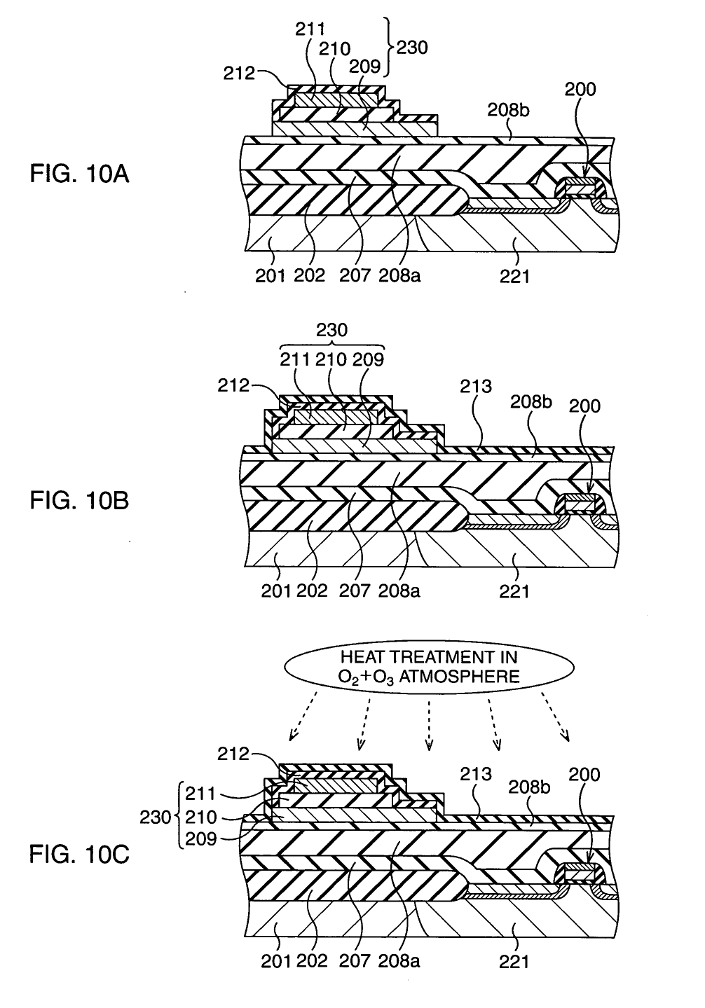

Next, as shown in FIG. 10A, by performing patterning of the Al₂O₃ film 212 and the Ir film 209a, a lower electrode 209 constituted of the Ir film 209a is formed. Thereby, a ferroelectric capacitor 230 including the lower electrode 209, the ferroelectric film 210 and the upper electrode 211 is formed. Thereafter, oxygen annealing for prevention of peeling-off of an Al₂O₃ film which will be formed later from is performed.

Next, as shown in FIG. 10B, an Al₂O₃ film 213 favorable in step coverage is formed on the entire surface. In this embodiment, the Al₂O₃ film 213 is formed with a thickness of about 20 nm by an ALD method using a batch type deposition apparatus.

On formation of the Al₂O₃ film 213 using the ALD method, a deposition process step using TMA which is liquid at a room temperature as an Al source, and an oxidation process step under the atmosphere of oxygen (O₂) and ozone (O₃) are alternately switched with a vacuum purge process step interposed between the process steps, and this is repeated by about 210 cycles, as the formation of the Al₂O₃ film 212 shown in FIG. 9B.

More specifically, the deposition process step using TMA is performed under the conditions of, for example, a substrate temperature of 300° C., gas pressure of 40 Pa (0.3 Torr), and a TMA gas flow rate of 100 sccm for 5 seconds. The oxidation process step is performed under the conditions of, for example, a substrate temperature of 300° C., gas pressure of 133 Pa (1.0 Torr), an O₂+O₃ gas flow rate of 10 slm, and an O₃ concentration of 200 g/Nm³ for 15 seconds. Since TMA is relatively high in vapor pressure, it is introduced into the batch type deposition apparatus in the state it is heated to a temperature of 40° C. and is gasified by the vapor pressure.

After formation of the Al₂O₃ film 213 is finished, densification annealing is subsequently performed by increasing the temperature in-situ under an atmosphere of oxygen (O₂) and ozone (O₃) as shown in FIG. 10C. On this occasion, increase of temperature is performed at about 10° C./min, and in order to stabilize the temperature, the temperature is kept at leas for 30 minutes after being increased. The densification annealing is performed under the conditions of, for example, a substrate temperature of 500° C., gas pressure of 133 Pa (1.0 Torr), an O₂+O₃ gas flow rate of 10 μm, and O₃ concentration of 200 g/Nm³ for 30 minutes.

As shown in FIGS. 9C and 10C, the Al₂O₃ films 212 and 213 become densified films by the annealing treatment in the atmosphere including ozone (O₃) having strong oxidative property. Thereby, even when hydrogen occurs in the post process of deposition of, for example, an interlayer insulating film or the like, entry of hydrogen into the ferroelectric film 210 can be inhibited, and deterioration of the ferroelectric film 210 can be prevented. Further, when deposition of the Al₂O₃ films 212 and 213 is respectively performed by an ALD method using TMA and H₂O, OH groups existing in each of the Al₂O₃ films can be collectively removed, and deterioration of the ferroelectric film 210 by a so-called steamed state can be avoided.

Next, as shown in FIG. 1A, an interlayer insulating film 214 is formed on the entire surface by an HDP-CVD (High Density Plasma CVD) method. The thickness of the interlayer insulating film 214 is, for example, about 1.5 μm.

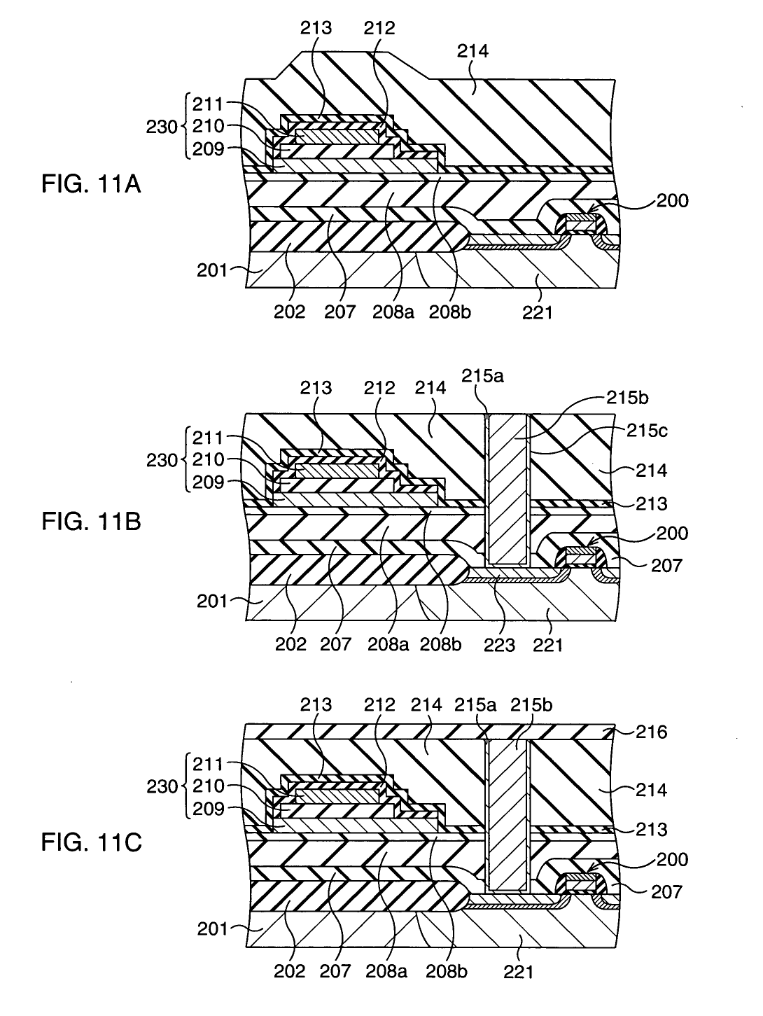

Next, as shown in FIG. 11B, flattening of the interlayer insulating film 214 is performed by a CMP (Chemical Mechanical Polishing) method. Thereafter, plasma treatment using an N₂O gas is performed. As a result, the surface layer portion of the interlayer insulating film 214 is slightly nitrided, and it is difficult for water to enter an inside thereof. It is effective to perform the plasma treatment by using a gas including at least one of N or O. Subsequently, a via hole 215c which reaches the high-concentration diffusion layer 223 of the MOSFET 200 is formed in the interlayer insulating film 214, the Al₂O₃ film 213, the Al₂O₃ film 208b, the silicon oxide film 208a and the silicon oxynitride film 207. Thereafter, a TiN film and a Ti film are successively stacked in the via hole 215c by, for example, a sputtering method, and thereby, a glue film 215a is formed on an inner wall of the via hole 215c. Subsequently, after a W film of a thickness sufficient for filling the inside of the via hole 215c is deposited by a CVD method, flattening of the W film is performed by a CMP method until the front surface of the interlayer insulating film 214 is exposed, and thereby, a W plug 215b is formed in the via hole 215c.

Next, as shown in FIG. 11C, a silicon oxynitride film (SiON film) 216 is formed as an oxidation preventing film for the W plug 215b by, for example, a plasma enhanced CVD method.

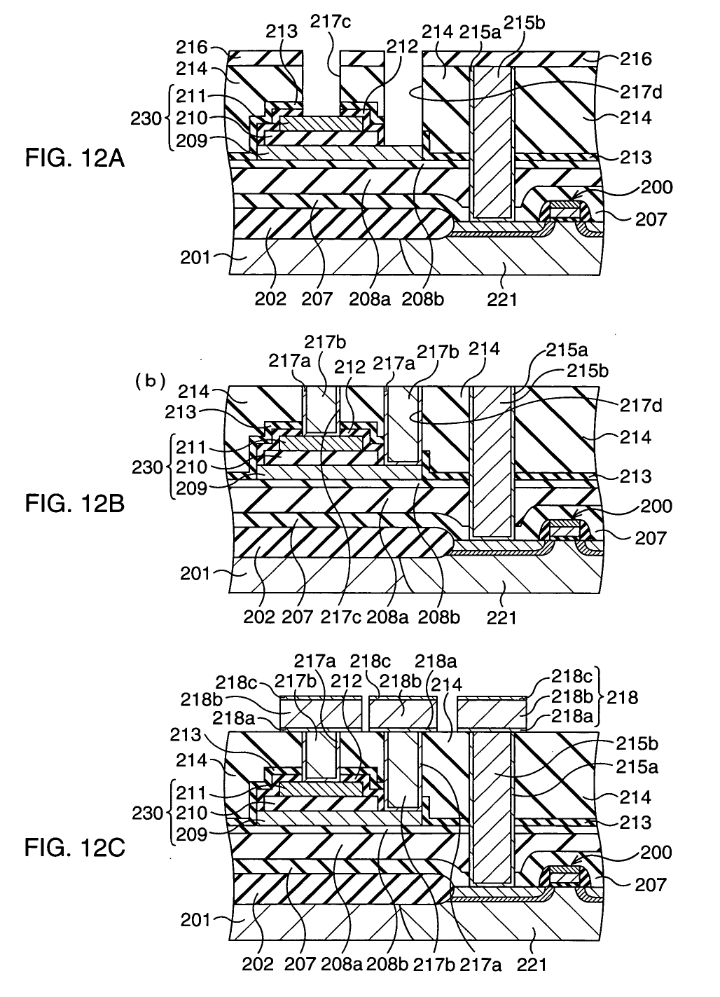

Next, as shown in FIG. 12A, by performing etching, a via hole 217c which reaches the upper electrode 211 and a via hole 217d which reaches the lower electrode 209 are formed in the silicon oxynitride film (SiON film) 216, the interlayer insulating film 214, the Al₂O₃ film 213 and the Al₂O₃ film 212. Thereafter, in order to repair the damage on the ferroelectric film 210 due to the influence of the etching, oxygen annealing is performed.

Next, as shown in FIG. 12B, by removing the silicon oxynitride film (SiON film) 216 from the entire surface by etchback, the front surface of the W plug 215b is exposed first. Subsequently, a TiN film and a Ti film are successively stacked in the via hole 217c and the via hole 217d by a sputtering method, and thereby, a glue film 217a is formed on an inner wall of each of the via holes. Subsequently, after a W film of a thickness sufficient for filling an inside of each of the via holes 217c and 217d is deposited by a CVD method, flattening of the W films is performed until the front surface of the interlayer insulating film 214 is exposed by a CMP method, and thereby, W plugs 217b are formed in the via hole 217c and the via hole 217d.

Next, as shown in FIG. 12C, a metal wiring layer 218 constituted of a glue film 218a, a wiring film 218b and a glue film 218c is formed.

More specifically, first, by, for example, a sputtering method, a Ti film of a thickness of about 60 nm, a TiN film of thickness of about 30 nm, an AlCu alloy film of a thickness of about 400 nm, a Ti film of a thickness of about 5 nm, and a TiN film of a thickness of about 70 nm are sequentially stacked on the entire surface. Subsequently, the stacked film is patterned into a predetermined shape by using a photolithograph technique, and the metal wiring layer 218 constituted of the glue film 218a constituted of the Ti film and the TiN film, the wiring film 218b constituted of the AlCu alloy film, and the glue film 218c constituted of the Ti film and the TiN film is formed on each of the W plugs 215b and 217b.

Thereafter, after formation of an interlayer insulating film and formation of contact plugs are further performed, the metal wiring layers of the second layer and thereafter are formed, the cover film constructed by the TEOS-SiO₂ film and the SiN film is finally formed, and a ferroelectric memory according to this embodiment, having the ferroelectric capacitor 230 is completed.

Next, the results of the experiments conducted by the inventor will be described.

First, the Al₂O₃ film was deposited with a thickness of about 20 nm on the silicon substrate by the ALD method by using the batch type deposition apparatus, and the H₂O content in the Al₂O₃ film was evaluated by using the TDS method. On this occasion, deposition of the Al₂O₃ film was performed by the ALD method using TMA and H₂O. As the evaluation sample, the sample which was produced by the manufacturing method of the present invention in which annealing treatment in the atmosphere including ozone (O₃) was performed after formation of the Al₂O₃ film, and the sample which was produced by the conventional manufacturing method in which annealing treatment in the atmosphere including ozone (O₃) was not performed after formation of the Al₂O₃ film were used. For the sample produced by the manufacturing method of the present invention, after the aluminum oxide film was formed, the temperature was increased to the temperature of 500° C. in-situ, and densification annealing for 30 minutes was performed in the O₃ atmosphere.

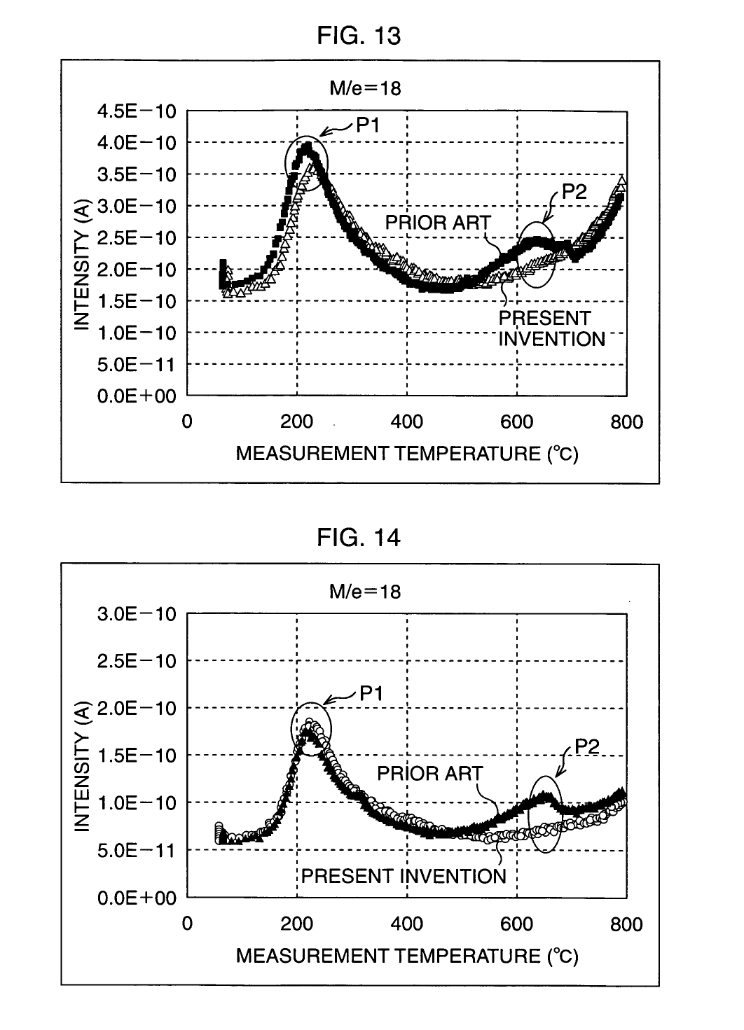

FIG. 13 is a characteristic chart showing the TDS analysis result when the Al₂O₃ film was deposited at the temperature of 300° C. FIG. 13 shows the characteristic of only the spectrum of M/e=18 corresponding to H₂O. In FIG. 13, the temperature region P1 in the vicinity of 220° C. is not taken into consideration because it is considered to be desorption of H₂O adsorbed on the surface of the aluminum oxide film as in the case of FIG. 1. The temperature region P2 in the vicinity of 650° C. showing H₂O generating from dehydration condensation reaction of OH groups of the Al—OH bond which exist in the aluminum oxide film in no small quantities is studied.

As shown in FIG. 13, when the Al₂O₃ film is deposited at a temperature of 300° C., in the temperature region P2, a peak is seen in the sample produced by the conventional manufacturing method, but in the sample produced by the manufacturing method of the present invention, a peak is not seen. This shows that the OH groups are removed from the Al₂O₃ film by the annealing treatment in the O₃ atmosphere, and the Al₂O₃ film is desified.

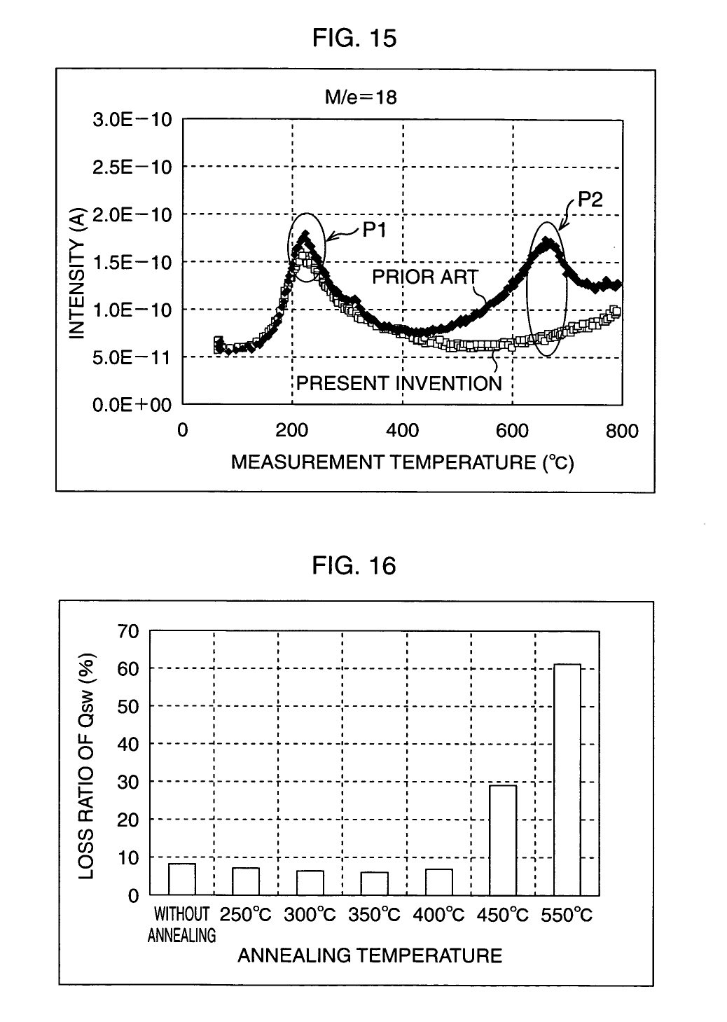

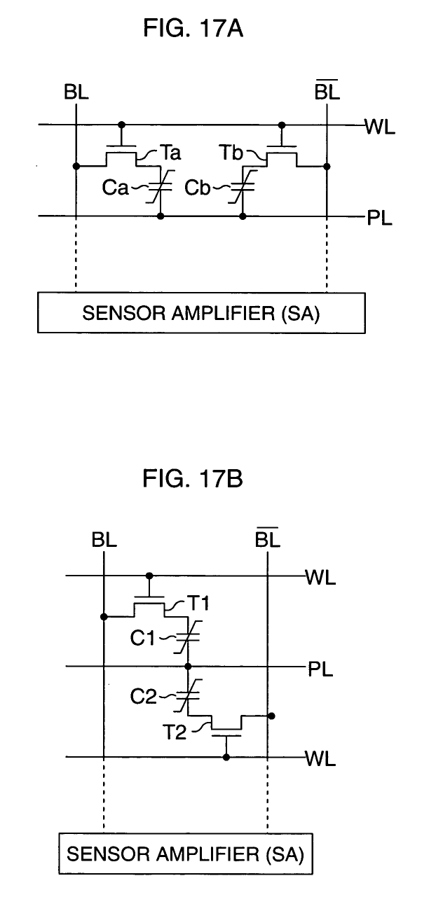

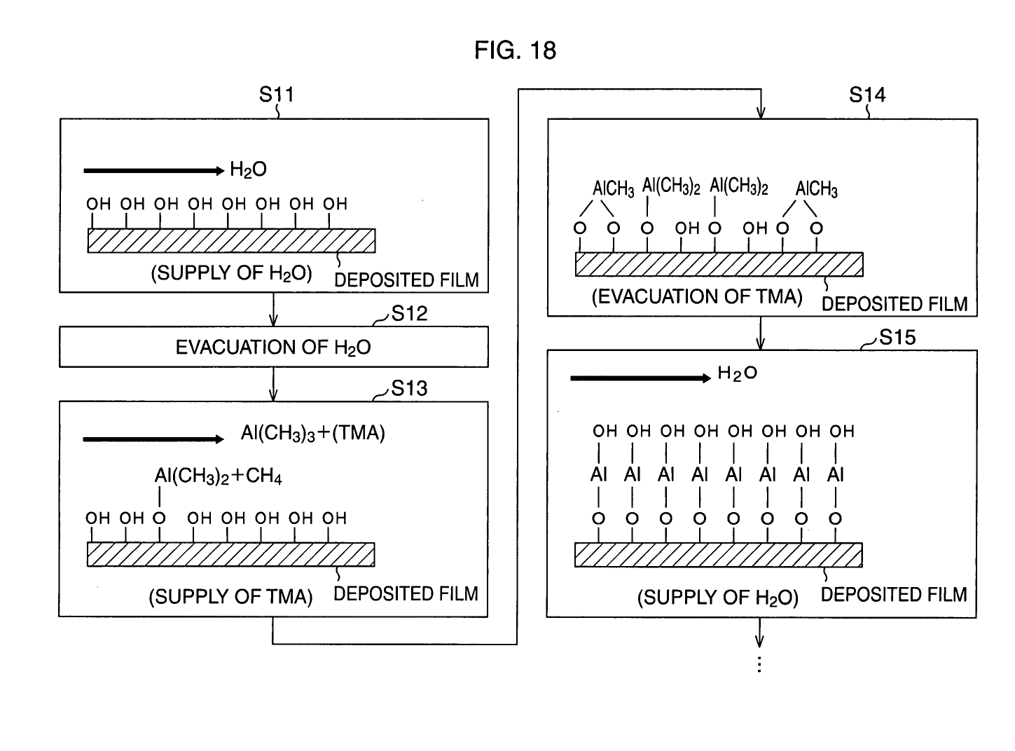

Similarly, FIG. 14 is a characteristic chart showing the TDS analysis result when the Al₂O₃ film is deposited at a temperature of 250° C., and FIG. 15 is a characteristic chart showing the TDS analysis result when the Al₂O₃ film is deposited at a temperature of 200° C. As in the case of FIG. 13, in the case of deposition temperatures of 250° C. and 200° C., in the temperature region P2, in the sample produced by the conventional manufacturing method, a peak is seen, but a peak is not seen in the sample produced by the manufacturing method of the present invention. It is found out that the OH groups are removed from the Al₂O₃ film by the annealing treatment in the O₃ atmosphere, and the Al₂O₃ film is densified.

Next, the result of the experiment for investigating the fatigue characteristic of the ferroelectric capacitor being conducted in order to evaluate the influence of the deposition temperature of the ALD method artificially is shown in FIG. 16.

As a sample, the lower electrode constituted of the Pt film and the Ti film, the ferroelectric film constituted of PLZT, and the ferroelectric capacitor including the upper electrode constituted of IrO₂ were formed by sequentially depositing the Pt film of a thickness of about 175 nm, the Ti film of a thickness of about 20 nm, PLZT of a thickness of about 200 nm and IrO₂ of a thickness of about 200 nm by the sputtering method, and performing patterning. Then, the aluminum oxide film was deposited by the sputtering method at the room temperature to cover all the ferroelectric capacitor processed into the band platform structure, after which, the single layer wiring of Al was deposited, and the sample was produced.

As for the fatigue characteristics of the ferroelectric capacitor, furnace annealing for 60 minutes was performed before deposition of the aluminum oxide film, and the deposition temperature was artificially reproduced. Then, the loss ratio (%) of the switching charge amount Qsw after the fatigue test of applying a voltage of 7 V and repeating inversion 2×10⁸ times was performed with the annealing temperature corresponding to the deposition temperature set as a parameter was measured.

As shown in FIG. 16, it is found out that when the annealing was performed at a temperature of 450° C. or higher, the loss ratio of the switching charge amount Qsw after the fatigue test becomes large. It is conceivable that since in the treatment at 450° C. or higher, the side walls of PLZT that is the ferroelectric film are exposed, PbO comes out of the side walls, and Pb desorption occurs. The furnace annealing is performed at normal pressure, but in the case of the ALD method which is a kind of a low pressure CVD method, deposition is performed at vacuum pressure, and therefore, it is conceivable that Pb desorption is promoted more. Considering this respect, in order to secure the operation of the reliable FeRAM, the deposition temperature of the Al₂O₃ film by an ALD method is desired to be 350° C. or lower. When the deposition temperature becomes lower than 200° C., there arises the problem that carbon remains in the Al₂O₃ film even if PDA treatment is performed, and therefore, it is desirable that the deposition temperature is 200° C. or higher.

The deposition apparatuses by the ALD method include single slice deposition apparatuses, and batch type deposition apparatuses each of which treat about 100 substrates by one operation. In the case of the ALD method which performs deposition of each layer, deposition takes time, and therefore, a batch type deposition apparatus is advantageous in view of throughput. However, since in the case of a batch type deposition apparatus, evacuation is performed for a large volume, cycle time for one layer is long as compared with the aluminum oxide film deposited with a single slice deposition apparatus, and there arises the fear that the film quality becomes poor and a porous film, and does not sufficiently function as the capacitor protection film. Thus, it is conceivable that if the deposition temperature is made high, the aluminum oxide film becomes denser and increases in block performance, but there is the fear of occurrence of particle since the probability of TMA reacting in the gas phase becomes high. Further, when the PZT film is used as the ferroelectric film of a ferroelectric capacitor, it is conceivable that since the vapor pressure of PbO that is a constituent substance is high, when it is deposited at a high temperature, PbO desorbs to make a film poor in Pb, and the fatigue characteristic, which is one of the indicators of the reliability evaluation, degrades.

Namely, when an aluminum oxide film is deposited with a batch type deposition apparatus in consideration of throughput, there is conventionally the comprehension that the film quality becomes poor or particle occurs during deposition. However, in the present invention, after forming an aluminum oxide film, annealing treatment including a strong oxidative ozone (O₃) is performed, whereby the aluminum oxide film is made a denser film, and as also obvious from the result of FIG. 16, deposition can be made without making the deposition temperature of the aluminum oxide film high, thus making it possible to eliminate occurrence of particle during deposition. Therefore, the present invention is more preferable in the case of deposition of an aluminum oxide film with a batch type deposition apparatus.

According to the embodiments of the present invention, annealing treatment is performed for the Al₂O₃ film (aluminum oxide film) which covers a ferroelectric capacitor in an oxidizing gas atmosphere including ozone (O₃). Therefore, the Al₂O₃ film can be made a dense film, entry of hydrogen into the ferroelectric film can be avoided, and deterioration of the ferroelectric film can be prevented. Thereby, a FeRAM having a ferroelectric capacitor having high switching charge amount Qsw, namely high reliability can be provided.

Deposition of the Al₂O₃ film is performed by the ALD method using TMA and ozone (O₃), and therefore, the Al₂O₃ film can be made a more densified film.

Since the Al₂O₃ film is formed at a temperature of 350° C. or lower, PbO desorption can be avoided when PZT (PLZT) is used as the ferroelectric film. Since annealing treatment at 350° C. or higher (500° C. in this embodiment) is performed for the Al₂O₃ film deposited at a low temperature of 350° C. or lower in the atmosphere including ozone (O₃) having a strong oxidative effect, desorption of PbO is blocked by the Al₂O₃ film, and degradation of fatigue characteristic of the ferroelectric capacitor can be prevented.

Since the process step of forming an Al₂O₃ film, and the annealing treatment process step using ozone (O₃) are successively performed in the same apparatus (in-situ), the problem that water adsorbed on the surface of the Al₂O₃ film is internally diffused by the subsequent furnace annealing to deteriorate the ferroelectric film can be avoided.

Further, when the aluminum oxide film that is a protection film for a ferroelectric capacitor is deposited by an ALD method by using a batch type deposition apparatus, the aluminum oxide film can be made a dense film, occurrence of particle can be avoided and degradation of fatigue characteristic can be prevented. Thereby, throughput in the manufacturing process can be enhanced.

In this embodiments, explanation is made with the example using PZT as the ferroelectric film of a ferroelectric capacitor, but the present invention is not limited to this, and for example, a PZT material such as La doped PZT (PLZT), and a Bi-layer structure compound such as SrBi₂Ta₂O₉ (SBT, Y1), and SrBi₂ (Ta, Nb)₂O₉ (SBTN, YZ) can be used. The case of forming the ferroelectric film by the MO-CVD method is described, but, for example, a sol-gel method, a sputtering method and the like can be used.

According to the present invention, even when manufacturing a fine ferroelectric memory, it becomes possible to prevent deterioration of a capacitor film.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A manufacturing method of a semiconductor device, comprising the steps of:
forming a capacitor formed by sandwiching a capacitor film between an upper electrode and a lower electrode;
forming an aluminum oxide film to cover the capacitor; and
after forming the aluminum oxide film, performing heat treatment for the aluminum oxide film in an oxidizing gas atmosphere including ozone.

2. The manufacturing method of a semiconductor device according to claim 1,
wherein the heat treatment is performed at a temperature of 400° C. to 700° C. inclusive.

3. The manufacturing method of a semiconductor device according to claim 1,
wherein the aluminum oxide film is formed at a temperature of 200° C. to 350° inclusive.

4. The manufacturing method of a semiconductor device according to claim 1,
wherein said step of forming the aluminum oxide film and said step of performing the heat treatment are successively performed in a same apparatus.

5. The manufacturing method of a semiconductor device according to claim 1,
wherein the aluminum oxide film is formed by a atomic layer deposition method.

6. The manufacturing method of a semiconductor device according to claim 5,
wherein in the atomic layer deposition method, an organic aluminum compound and an oxidizing gas are used.

7. The manufacturing method of a semiconductor device according to claim 6,
wherein as the oxidizing gas, ozone is used.

8. The manufacturing method of a semiconductor device according to claim 6,
wherein as the organic aluminum compound, tri-methyl aluminum is used.

9. The manufacturing method of a semiconductor device according to claim 1,
wherein the aluminum oxide film is formed in a batch type apparatus.

10. The manufacturing method of a semiconductor device according to claim 1,
wherein the capacitor film is constituted of a ferroelectric film.

11. The manufacturing method of a semiconductor device according to claim 10,
wherein the ferroelectric film is at least any one kind of PZT (lead zirconate titanate), PLZT (lead lanthanum zirconate titanate), SBT (strontium bismuth tantalum) and SBTN (strontium bismuth tantalum niobate).

12. The manufacturing method of a semiconductor device according to claim 1,
wherein the upper electrode is constituted of a film containing iridium oxide.
